(19) United States
(12) Patent Application Publication
(10) Pub. No.: US 2014/0007808 A1
(43) Pub. Date: Jan. 9, 2014

(54) Susceptor Device And Deposition Apparatus Having The Same

(71) Applicants: Akira Okabe, Ohmura-shi (JP); Masanori Tanoguchi, Ohmura-shi (JP); Yoshinobu Mori, Ohmura-shi (JP)

(72) Inventors: Akira Okabe, Ohmura-shi (JP); Masanori Tanoguchi, Ohmura-shi (JP); Yoshinobu Mori, Ohmura-shi (JP)

(73) Assignee: Epicrew Corporation, Nagasaki (JP)

(21) Appl. No.: 14/003,369

(22) PCT Filed: May 16, 2012
(86) PCT No.: PCT/JP2012/062548

§ 371 Date: Sep. 24, 2013

(30) Foreign Application Priority Data
Jul. 5, 2011 (JP) 2011-149524

(51) Int. Cl. C30B 25/12

(52) U.S. Cl. CPC C30B 25/12
USPC 118/500

(57) ABSTRACT

A susceptor device includes: a placement section on which a substrate is placed; a lift pin which is provided in the placement section and protrudes further to the upper side than the placement section at the time of carrying-in or carrying-out of the substrate, thereby supporting the substrate placed on the placement section; and lift pin moving means for moving the lift pin up and down. At the time of carrying-in or carrying-out of the substrate, the substrate is moved up and down by moving the lift pin up and down by the lift pin moving means in a state where the substrate is supported by the lift pin, and the susceptor device further includes a control section which controls the lift pin moving means so as to reduce a movement speed immediately before the substrate and the lift pin come into contact with each other, in a case of moving the lift pin.

### BACKGROUND OF THE INVENTION

1. Field of the Invention

The present invention relates to a susceptor device and a deposition apparatus having the same.

2. Background Art

Usually, in a deposition apparatus, a substrate carried into a load lock chamber carried into deposition chamber by a robot and the substrate is placed on a susceptor device. Then, a technique is known in which a tip of a pin is brought into contact with the substrate and the pin is moved up and down in this state, whereby up-and-down motion of the substrate is performed (refer to, for example, Japanese Unexamined Patent Application Publication No. 2006-41028 (Paragraph 0020 and the like)).

### SUMMARY OF THE INVENTION

In a case of moving the substrate up and down in this manner, assuming that the substrate is moved up and down by moving the pin up and down by using an air cylinder, height adjustment of a stop position is difficult. Further, in a case of moving the pin by the air cylinder, there is a problem in that an installation position of the substrate is shifted in a plane direction due to impact or the like at the time of contact of the pin with the substrate. On the other hand, if up-and-down motion of the substrate is performed with a reduced movement speed in order to suppress impact at the time of contact of the pin with the substrate, productivity is reduced.

Therefore, an object of the present invention is to solve the problem of the above-described related art and provide a susceptor device in which productivity is not reduced and impact occurring in a substrate at the time of movement of the substrate can be suppressed, and a deposition apparatus having the same.

According to an aspect of the invention, there is provided, a susceptor device including: a placement section on which a substrate is placed; a lift pin which is provided in the placement section and protrudes further to the upper side than the placement section at the time of carrying-in or carrying-out of the substrate, thereby supporting the substrate placed on the placement section; and lift pin moving means for moving the lift pin up and down, in which at the time of carrying-in or carrying-out of the substrate, the substrate is moved up and down by moving the lift pin up and down by the lift pin moving means in a state where the substrate is supported by the lift pin, and the susceptor device further includes a control section which controls the lift pin moving means so as to reduce a movement speed immediately before the substrate and the lift pin come into contact with each other, in a case of moving the lift pin. With such a configuration, it is possible to suppress impact in a case where the lift pin and the substrate come into contact with each other and it is possible to suppress a shift of an installation position the substrate in a plane direction. Further, a movement speed is reduced immediately before the contact, whereby the entire deposition cycle is not reduced.

It is preferable that the susceptor device according to the above aspect of the invention further include placement section moving means for moving the placement section up and down, in which the control section controls, during deposition of the substrate, the placement section moving means so as to reduce a movement speed immediately before the substrate supported on the lift pin and the placement section come into contact with each other, when moving the placement section up and down by controlling the placement section moving means. With such a configuration, a shift of an installation position of the substrate in a plane direction can be further suppressed.

In the susceptor device according to the above aspect of the invention, it is preferable that the control section control the lift pin moving means so as to reduce a movement speed immediately before the substrate and a substrate transport device come into contact with each other, in a case of moving the substrate in a state where the substrate is supported by the lift pin. With such a configuration, a shift of an installation position of the substrate in a plane direction can be further suppressed.

In the susceptor device according to the above aspect of the invention, it is preferable that the lift pin moving means and the placement section moving means be electric cylinders. This is because, if it is an electric cylinder, it is easy to perform movement control.

According to another aspect of the invention, there is provided a deposition apparatus including: the susceptor device according to any one of the above.

### BRIEF DESCRIPTION OF THE DRAWINGS

FIG. 1 is a schematic diagram showing the configuration of a deposition apparatus.

FIG. 2 is a schematic cross-sectional view showing the configuration of a susceptor device.

FIGS. 3A to 3D are schematic cross-sectional views showing an operation of the susceptor device.

FIGS. 4A to 4D are schematic cross-sectional views showing an operation of the susceptor device.

FIGS. 5A to 5D are schematic cross-sectional views showing an operation of the susceptor device.

FIGS. 6A and 6B are schematic cross-sectional views showing an operation of the susceptor device.

### DETAILED DESCRIPTION OF THE INVENTION

A susceptor device according to the invention will be described.

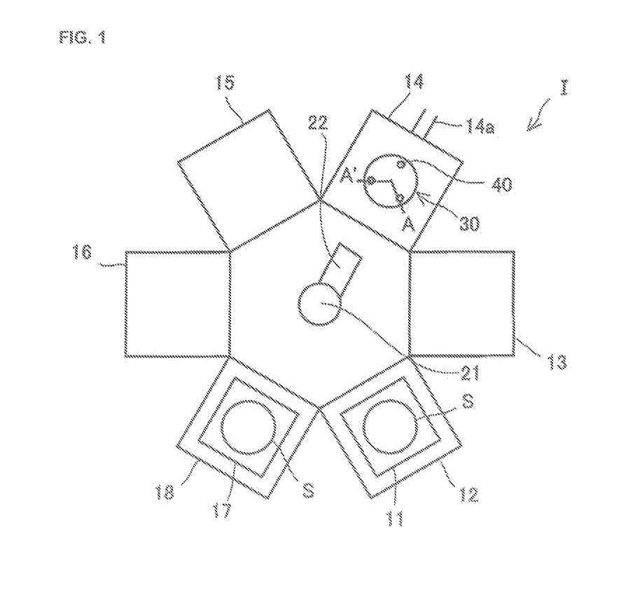

As shown in FIG. 1, a deposition apparatus I on which a susceptor device 30 is mounted is a single wafer type deposition apparatus. The deposition apparatus I includes a first load lock chamber 12 in which a first substrate cassette 11 with a substrate S for deposition stored therein is placed, a second load lock chamber 18 in which a second substrate cassette 17 is placed, and treatment chambers 13 to 16, in which each treatment which includes deposition treatment is performed. Each of the treatment chambers 13 to 16, the first load lock chamber 12, and the second load lock chamber 18 is provided with evacuation means (not shown), and it is possible to independently maintain the degree of vacuum in each chamber. In this embodiment, the treatment chamber 14 among the treatment chambers 13 to 16 is a deposition chamber in which treatment to form a film by epitaxial growth on the substrate S is performed.

Further, the deposition apparatus I is provided with a robot (a substrate transport device) 21 for transporting the substrate S to each chamber. The robot 21 has a blade 22 on which the substrate S is placed. The width of the blade 22 is provided so as to be smaller than the width of the substrate S.

The susceptor device 30 according to the invention is installed in the treatment chamber 14. The substrate S is placed on the susceptor device 30. Further, deposition gas introduction means 14a for introducing deposition gas into the treatment chamber 14 is provided in the treatment chamber 14. A deposition surface of the substrate S on the susceptor device 30 is moved to a predetermined deposition position by the susceptor device 30 and a film by an epitaxial growth method is formed at the deposition position.

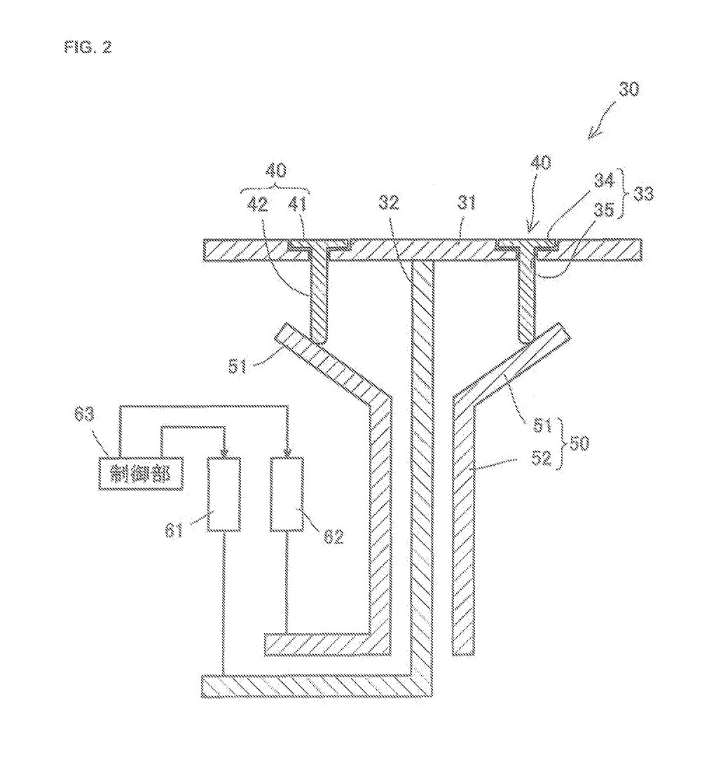

The susceptor device will be described using FIG. 2.

The susceptor device 30 has a placement section 31 in which the substrate is placed on the front surface side thereof. The placement section 31 has a circular shape in to view. At the placement section 31, a placement section shaft 32 is provided on the rear surface side thereof. The placement section 31 is supported by the placement section shaft

A through-hole 33 penetrating the placement section 31 is provided in the placement section 31. The through-hole 33 has a first penetration portion 34 opened to the front surface side of the placement section 31, and a second penetration portion 35 opened to the rear surface side of the placement section 31. The second penetration portion 35 is provided such that the diameter thereof is smaller than the diameter of the first penetration portion 34. That is, the through-hole 33 has a T shape in the cross-sectional view, as shown in the drawing. The through-hole 33 is provided in the placement section 31 so as to be located further to the inside than an edge portion of the substrate in a case where the substrate is placed.

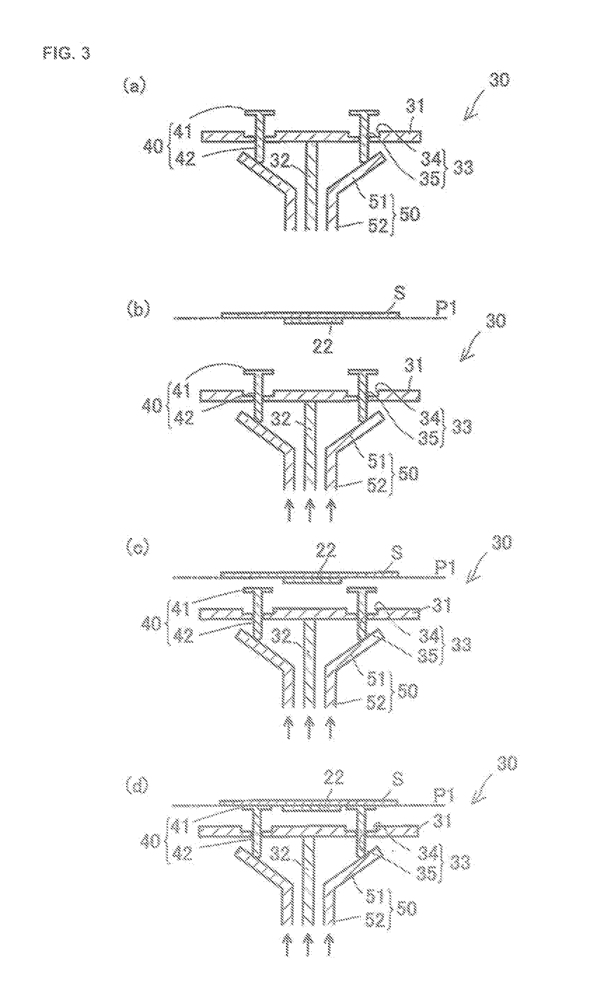

A lift pin 40 is installed in the through-hole 33. Three lift pins 40 are provided with respect to a single susceptor device 30. Each lift pin 40 is provided at a distance wider than the width of the blade 22 (refer to FIG. 3B) with respect to an adjacent lift pin 40. The lift pin 40 has a support portion 41 configured such that the diameter thereof is slightly smaller than the diameter of the first penetration portion 34, and a pin portion 42 provided integrally with the support portion 41 and configured such that the diameter thereof is slightly smaller than the diameter of the second penetration portion 35. That is, the lift pin 40 also has a T shape in the cross-sectional view, as shown in the drawing. The support portion 41 is a portion on which the substrate is placed when transported into the deposition chamber, as will be described later, and the surface thereof is configured so as to he horizontal with respect to a floor surface. The support portion 41 has the same depth as the first penetration portion 34, and the support portion 41 is supported on the bottom surface of the first penetration portion 34. The pin portion 42 extends in a direction perpendicular to the floor surface. Since the lift pin 40 is configured such that the diameter is slightly smaller than the diameter of the through-hole 33, as described above, it is possible to move the lift pin 40 in the through-hole 33 by pressing the lift pin 40 vertically upward with respect to the floor surface from the lower side.

In the susceptor device 30, a wafer lift member 50 is further provided. The wafer lift member 50 has an inclined lift pin support portion 51 and a tubular shaft portion 52 of a cylindrical shape provided integrally with the lift pin support portion 51. The lift pin support portion 51 is an arm-shaped support member extending upward and outward from an upper end portion of the tubular shaft portion 52 and is located so as to face an end portion of the pin portion 42 of each lift pin 40. That is, in this embodiment, three lift pin support portions 51 are provided at the upper end portion of the tubular shaft portion 52 and each lift pin support portion 51 supports each lift pin 40 from the lower side thereof.

The wafer lift member 50 and the placement section shaft 32 are respectively provided with electric cylinders 61 and 62 in order to Perform an up-and-down motion perpendicular to the floor surface. That is, the first electric cylinder (placement section moving means) 61 is provided at the placement section shaft 32 and the second electric cylinder (lift pin moving means) 62 is provided at the tubular shaft portion 52 of the wafer lift member 50. A control signal is individually transmitted from a control section 63 to each of the electric cylinders 61 and 62, and thus the up-and-down motion is performed individually.

Then, the control signals are transmitted to the electric cylinders 61 and 62 by the control section 63, whereby the electric cylinders 61 and 62 respectively move the tubular shaft portion 52 and the placement section shaft 32, thereby moving the substrate. A case of moving the substrate refers so a case where the robot places the substrate on the susceptor device 30, a case of moving the substrate to a deposition position, and a case where the robot carries the substrate out. Then, in each case of moving the substrate, since the substrate and a member constituting the susceptor device 30 or the blade come into contact with each other, it is conceivable that the substrate is shifted in a plane direction due to the impact. Further, it is conceivable that small scratches or cracks are generated in the substrate due to the impact. Therefore, in this embodiment, movement control of the substrate is performed by the control section 63 such that it is possible to efficiently perform a series of treatment on the substrate by suppressing impact which occurs in the substrate and also improving productivity. That is, in this embodiment, a configuration is made such that the movement of the susceptor device 30 is controlled by controlling the movement speeds of the placement section shaft 32 and the tubular shaft portion 52 by the electric cylinders 61 and 62 at two stages by the control section 63, as described below, whereby it is possible to efficiently perform a series of treatment on the substrate by improving productivity while suppressing impact which occurs in the substrate when the substrate moves.

Hereinafter, an operation of the susceptor device 30 in a series of treatment will be described using FIG. 3A to FIG. 6B.

FIGS. 3A to 3D are for explaining an operation of the susceptor device 30 from prior to the substrate carry-in to the substrate installation.

As shown in FIG. 3A, prior to the substrate carry-in, since the distance between the upper end portion of the wafer lift member 50 and the placement section 31 is shorter than the length of the lift pin 40, the lift pin 40 is supported on the wafer lift member 50, thereby protruding further to the upper side than the placement section 31.

Subsequently, as shown in FIG. 3B, the blade 22 of the robot 21 (refer to FIG. 1) is introduced into the deposition chamber. On the blade 22, the substrate S is placed. The substrate S is placed on the blade 22 so as to be located at a transport position P1, and then carried in. The width of the substrate S is wider than the width of the blade 22 and the substrate S is placed on the blade 22 such that the central portion of the substrate S is supported.

Then, if the blade 22 is introduced into the deposition chamber, each of the electric cylinders 61 and 62 (refer to FIG. 2) is operated by the control section 63 (refer to FIG. 2), whereby the placement section shaft 32 and the tubular shaft portion 52 starts to simultaneously move upward at the same movement speed. In this case, the movement speed is controlled by the control section 63 so as to become a first movement speed. In addition, the first movement speed is faster than a second movement speed. In this embodiment, the first movement speed is 20 mm/s and the second movement speed is 5 mm/s.

Each of the electric cylinders 61 and 62 is operated by the control section 63, whereby the placement section shaft 32 and the tubular shaft portion 52 simultaneously move upward at the same movement speed. Then, as shown in FIG. 3C, if the placement section shaft 32 and the tubular shaft portion 52 rise to a position where the support portion 41 of the lift pin 40 and the substrate S are close to each other, the movement speeds of the placement section shaft 32 and the tubular shaft portion 52 are switched to the second movement speed by the control section 63 (refer to FIG. 2). That is, the movement speeds of the placement section 31 and the lift pin 40 are reduced.

Then, as shown in FIG. 3D, the placement section shaft 32 and the tubular shaft portion 52 are still moving at the second movement speed, whereby the support portion 41 of the lift pin 40 comes into contact with the rear surface of the substrate S. In this case, since the movement speeds of the placement section 31 and the lift pin 40 are reduced, as described above, impact in a case where the support portion 41 comes into contact with the rear surface of the substrate S is small, and thus the substrate S is not shifted in a plane direction.

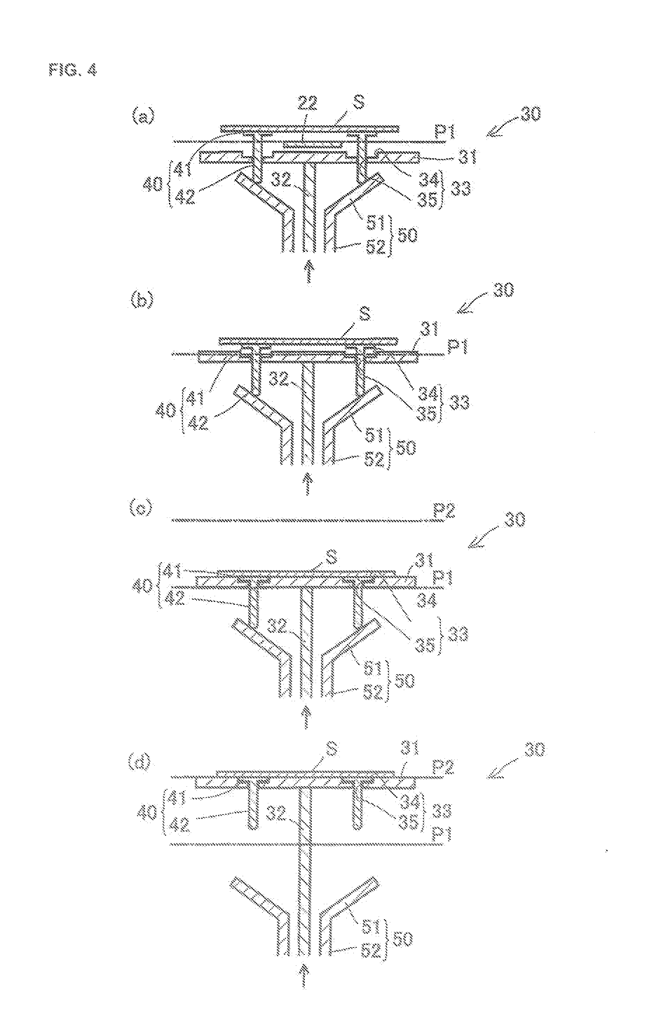

An operation of the susceptor device 30 from a state where the support portion 41 comes into contact with the rear surface of the substrate S in this manner to movement to a deposition position will be described using FIGS. 4A to 4D.

As shown in FIG. 4A, if the support portion 41 comes into contact with the rear surface of the substrate S, the blade 22 and the substrate S are separated from each other. Then, in this state, if the placement section shaft 32 and the tubular shaft portion 52 are further moved upward with the movement speed switched to the first movement speed, the distance between the blade 22 and the substrate S becomes wider in a state where the substrate S is supported by only the support portion 41 of the lift pin 40. The blade 22 is carried out of the deposition chamber.

Next, after the blade 22 is carried out, only the placement section shaft 32 is moved at the first movement speed, whereby only the placement section 31 is moved to a side of the substrate S supported by the lift pin 40. Then, as shown in FIG. 4B, if the placement section 31 is moved at the first movement speed to a position where the substrate S and the placement section 31 are close to each other, the control section 63 switches the movement speed of the placement section shaft 32 which moves the placement section 31 so as to become the second movement speed and then raises the placement section shaft 32, that is, the placement section 31 as it is.

Next, as shown in FIG. 4C, the placement section 31 moves upward at the second movement speed, thereby coming into contact with the rear surface of the substrate S supported on the lift pin 40. Also in this case, since the movement speed of the placement section shaft 32 is reduced, as described above, impact in a case where the placement section 31 comes into contact with the rear surface of the substrate S is small, and thus the substrate S is not shifted.

Subsequently, if the substrate S is placed on the placement section 31, the control section switches and raises the movement speed of the placement section 31 again so as to become the first movement speed and raises the placement section 31 as it is as shown in FIG. 4D. If the placement section 31 rises, the lift pin 40 and the lift pin support portion 51 are separated from each other and a rise of the placement section 31 is stopped at a predetermined deposition position P2.

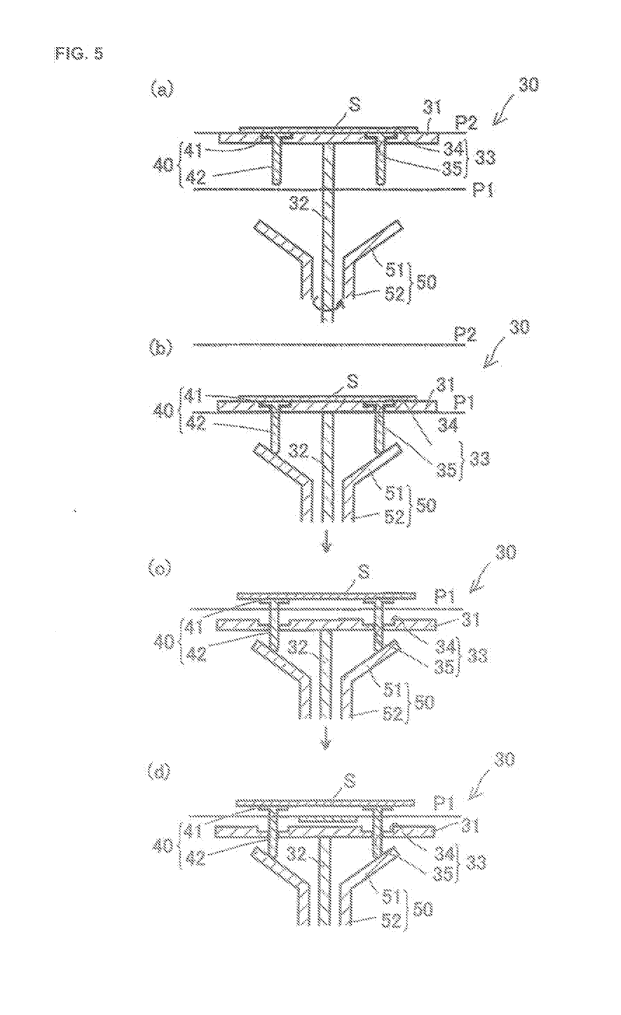

Next, an operation of the susceptor device 30 from the time of deposition to the time of start of substrate carry-out will be described using FIGS. 5A to 5D.

As shown in FIG. 5A, if the substrate S placed on the placement section 31 is moved to the deposition position P2, deposition is started. During she deposition, the placement section shaft 32 rotates with the placement section shaft 32 itself as the axis center, and thus, a film is uniformly formed on the substrate S.

If the deposition is finished, the placement section shaft 32 moves downward at the first movement speed. That is, only the placement section 31 descends at the first movement speed. Then, if the lift pin 40 and the lift pin support portion 51 come close to each other, the downward movement speed of the placement section 31 is switched to the second movement speed.

Then, as shown in FIG. 5B, if the lift pin 40 comes into contact with the lift pin support portion 51, impact of the contact is transmitted to the substrate S. However, even in this case, since the movement speed of the lift pin 40 is the second movement speed and is relatively slow, impact occurring in the substrate S is small, and thus a shift of the substrate S is suppressed.

Thereafter, as shown in FIG. 5C, since the lift pin 40 comes into contact with the lift pin support portion 51, whereby the placement section 31 and the substrate S are separated from each other, only the placement section 31 moves downward at the first movement speed in this state. In this way, the distance between the placement section 31 and the substrate S becomes wider. Then, as shown in FIG. 5D, the blade 22 is carried into the deposition chamber. In this case, the blade 22 is inserted into the gap between the placement section 31 and the substrate S such that the substrate S is located at the transport position in a case where the substrate S has been placed on the blade 22. Thereafter, each of the placement section shaft 32 and the tubular shaft portion 52 is further moved downward at the first movement speed to a position where the distance between the blade 22 and the substrate S come close to each other.

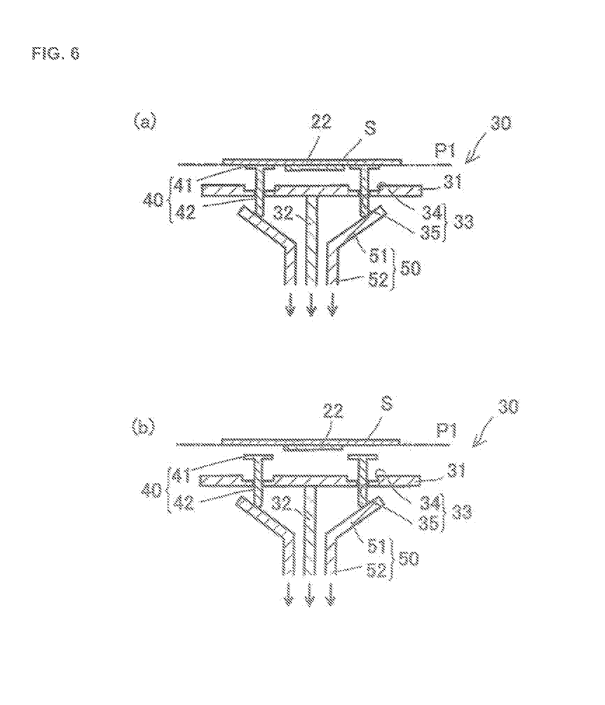

An operation until, the substrate S is carried out of the deposition chamber will be described using FIGS. 6A and 6B.

The placement section shaft 32 and the tubular shaft portion 52 are moved downward at the second movement speed from a position where the distance between the blade 22 and the substrate S come close to each other, whereby the substrate S is placed on the blade 22, as shown in FIG. 6A. Also in this case, if the substrate S is placed on the blade 22, impact at the time of the placement is transmitted to she substrate S. However, even in this case, since the movement speed of the substrate S is the second movement speed and is relatively slow, impact occurring in the substrate is small, and thus a shift of the substrate S is suppressed.

Thereafter, as shown in FIG. 6B, if the substrate S is placed on the blade 22, the placement section shaft 32 and the tubular shaft portion 52 are further moved downward at the first movement speed such that the substrate S is supported by only the blade.

Finally, the substrate S can be transported to the next treatment chamber by carrying the blade 22 out of the deposition chamber in a state where the substrate S is placed on the blade 22.

In this manner, in this embodiment, by moving the susceptor device 30 at the second movement speed in a case where impact occurs in the substrate S at the time of contact of the substrate S with a separate body and also moving the susceptor device 30 at the first movement speed at other locations, a shift of the substrate S is efficiently prevented by suppressing impact. The case where impact occurs in the substrate S at the time of contact of the substrate S with a separate body refers to a case where the substrate S and the support portion 41 come into contact with each other, which is shown in the case of FIG. 3D described, above, a case where the substrate S and the placement section 31 come into contact with each other, which is shown in FIG. 4C, a case where the lift, pin. 40 and the lift pin support portion 51 come into contact with each other in a state where the substrate S is placed on the lift pin 40, which is shown in FIG. 5B, and a case where the substrate S is placed on the blade 22, which is shown in FIG. 6A. That is, in this embodiment, by reducing a movement speed immediately before the substrate S and the lift pin 40 or the placement section 31 come into contact with each other, a shift of the substrate S is efficiently prevented by suppressing impact. Here, the expression, immediately before the substrate S and the lift pin 40 or the placement section 31 come into contact with each other, refers to when the distance between the substrate S and the lift pin 40 or the placement section 31 is less than or equal to 10 mm, preferably, in a range of 3 mm to 6 mm. If the distance between the two is longer than 10 mm, it is difficult to reduce a cycle time. Then, by using a preferable range, it is possible to most efficiently suppress impact.

A cycle time for a piece of substrate by the susceptor device according to this embodiment is about 5% shorter than a cycle time of a susceptor device (a susceptor device which moves each shaft by an air cylinder, rather than an electric cylinder) which does not depend on this embodiment. Further, a shift of a substrate does not occur. Accordingly, it is found that by using the susceptor device in this embodiment, a shift of the substrate can be suppressed by suppressing impact and productivity can be improved.

In this embodiment, movement is performed with the first movement speed set to be 20 mm/s and the second movement speed set to be 5 mm/s. However, as for the speed, if the first movement speed is faster than 5 mm/s and is less than or equal to 50 mm/s and the second movement speed is faster than 0 mm/s and is less than or equal to 5 mm/s, it is possible to preferably obtain the effects of the invention. If the second movement speed is faster than 5 mm/s, there is a case where the substrate is easily shifted, and if the first movement speed is less than or equal to 5 mm/s, it is not possible to efficiently perform deposition. In addition, it is preferable that the second movement speed be close to 5 mm/s, because in this case, it is possible to efficiently perform deposition. On the other hand, if the first movement speed is faster than 50 mm/s, there is a problem in that the substrate is shifted or sprung. Therefore, it is preferable that each movement speed be in the range described above.

Further, each speed may be determined in more detail in the above-described range the movement speed according to, for example, the weight of the substrate, a surface shape, the pressure in the deposition chamber, or the like. The heavier the substrate, the rougher the surface roughness, or the closer the pressure is to atmospheric pressure, the more it is difficult for the substrate to be shifted at the time of contact, and therefore, the speed may be fast.

In this embodiment, switching of the movement speed is performed at the locations of FIG. 3D, FIG. 4C, FIG. 5B, and FIG. 6A. However, it is not limited thereto. For example, a configuration may be made such that the switching is performed at least only at the time of contact of the substrate with the lift pin. If it is this range, it is possible to improve productivity and also suppress a shift of the substrate by suppressing impact occurring in the substrate.

In this embodiment, the susceptor device according to the invention is used in the deposition chamber in which epitaxial deposition is performed. However, it is not limited thereto. For example, the susceptor device may be used in other CVD apparatuses or the like.

In this embodiment, the susceptor device is configured so as to rotate during deposition. However, it is not limited thereto. For example, according to a deposition method, the susceptor device need not rotate during deposition.

In this embodiment, the deposition apparatus has a plurality of treatment chambers. However, it is not limited thereto. A deposition apparatus having only a deposition chamber in which a susceptor device is provided is also acceptable.

In this embodiment, each chamber is provided with the evacuation means. However, it is not limited thereto. Each chamber need not have the evacuation means.

In the invention, electric cylinders are used as the placement section moving means and the lift pin moving means. However, it is not limited thereto. It is acceptable if it is means capable of adjusting a movement speed.

What is claimed is:

1. A susceptor device comprising:
a placement section on which a substrate is placed;
a lift pin which is provided in the placement section and protrudes further to the upper side than the placement section at the time of carrying-in or carrying-out of the substrate, thereby supporting the substrate placed on the placement section; and
lift pin moving means for moving the lift pin up and down,
wherein at the time of carrying-in or carrying-out of the substrate, the substrate is moved up and down by moving the lift pin up and down by the lift pin moving means in a state where the substrate is supported by the lift pin, and
the susceptor device further comprises a control section which controls the lift pin moving means so as to reduce a movement speed immediately before the substrate and the lift pin come into contact with each other, in a case of moving the lift pin.

2. The susceptor device according claim 1, further comprising:
placement section moving means for moving the placement section up and down,
wherein the control section controls, during deposition of the substrate, the placement section moving means so as to reduce a movement speed immediately before the substrate supported on the lift in and the placement section come into contact with each other, when moving the placement section up and down by controlling the placement section moving means.

3. The susceptor device according to claim 1 or 2, wherein the control section includes a control section which controls the lift pin moving means so as to reduce a movement speed immediately before the substrate and a substrate transport device come into contact with each other, in a case of moving the substrate in a state where the substrate is supported by the lift pin.

4. The susceptor device according to claim 2 or 3, wherein the lift pin moving means and the placement section moving means are electric cylinders.

5. A deposition apparatus comprising the susceptor device according to any one of claims 1 to 4.
